(19) United States
(12) Patent Application Publication
(10) Pub. No.: US 2009/0121247 A1
(43) Pub. Date: May 14, 2009

(54) SEMICONDUCTOR LIGHT EMITTING DEVICE

(75) Inventor: Kouji TSUKAGOSHI, Ohta-Shi (JP)

Correspondence Address: WILMERHALE/DC, 1875 PENNSYLVANIA AVE., NW, WASHINGTON, DC, 20006, US

(73) Assignee: SANKEN ELECTRIC CO., LTD., Saitama-Ken (JP)

(21) Appl. No.: 12/242,324

(22) Filed: Sep. 30, 2008

(30) Foreign Application Priority Data
Nov. 12, 2007 (JP) 2007-008734

(51) Int. Cl. H01L 33/00

(52) U.S. Cl. 257/98; 257/E33.072

(57) ABSTRACT

A semiconductor light emitting device includes: a base portion having a concaved portion; a light emitting element provided in the concaved portion; a resin filled in the concaved portion; and a phosphor contained resin layer containing a wave converting substance and provided to close an opening portion of the concaved portion. The phosphor contained resin layer has a lower thermal expansion coefficient than the resin filled in the concaved portion.

### CROSS-REFERENCE TO RELATED APPLICATIONS

This application is based upon and claims priority from Japanese Utility Model Application No. 2007-8734 filed on Nov. 12, 2007, the entire contents of which are incorporated herein by reference.

### BACKGROUND OF THE INVENTION

1. Technical Field

The present invention is related to a semiconductor light emitting device. More specifically, the present invention is directed to a semiconductor light emitting device in which a light emitting element is provided in a concaved portion of a base portion.

2. Description of the Related Art

JP-A-2003-46133 describes a semiconductor light emitting device. The semiconductor light emitting device includes a light emitting diode chip is fixed on the concaved portion of the base portion, and the concaved portion is filled with the resin. The opening portion of the concaved portion is closed by the phosphor contained resign layer that contains the wave converting substance.

### BRIEF SUMMARY OF THE INVENTION

Recently, there is a need of high luminance of the semiconductor light emitting device in this technical field, and an increase of the luminance result in an increase of a heat generation amount of the light emitting diode chip. As described above, the inner space of the concaved portion is filled with resin. Therefore, the resin filled in the resin filled portion may expand due to heat generated from the light emitting diode chip. The expansion of the resin changes a distance between a surface of the light emitting diode chip and the phosphor contained resin layer, which causes a color fluctuation.

Also, the semiconductor light emitting device may be used in an outdoor field. In this case, the semiconductor light emitting device may be used under an atmospheric environment containing relatively large amount of impurities such as sulfur. Under such a use environment, when the impurities present in the atmosphere may enter in the inner portion of the resin filled portion, which may deteriorate a reflecting plate portion of the base portion. The deterioration of the reflecting plate portion lowers a light deriving efficiency of the semiconductor light emitting device and changes wavelengths, which deteriorates reliability of the semiconductor light emitting device lowers the luminance.

An object of one aspect of the invention is to provide a semiconductor light emitting device capable of reducing a deformation of the resin filled portion caused by an expansion of resin. An object of another aspect of the invention is to provide a semiconductor light emitting device capable of preventing impurities present in the atmospheric environment from entering in the inner portion of the resin filled portion.

According to an aspect of the invention, there is provided a semiconductor light emitting device comprising: a base portion having a concaved portion; a light emitting element provided in the concaved portion; a resin filled in the concaved portion; and a phosphor contained resin layer containing a wave converting substance and provided to close an opening portion of the concaved portion, wherein the phosphor contained resin layer has a lower thermal expansion coefficient than the resin filled in the concaved portion.

According to another aspect of the invention, there is provided a semiconductor light emitting device comprising: a base portion having a concaved portion; a light emitting element provided in the concaved portion; a resin filled in the concaved portion; and a phosphor contained resin layer containing a wave converting substance and provided to close an opening portion of the concaved portion, wherein the phosphor containing resin layer has higher crosslink density than the resin filled in the concaved portion.

### BRIEF DESCRIPTION OF THE DRAWING

FIG. 1 is a cross-sectional view showing a semiconductor light emitting device according to an embodiment of the invention.

### DETAILED DESCRIPTION OF THE EMBODIMENT

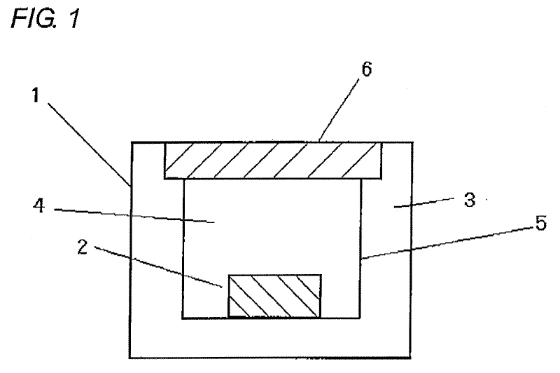

As shown in FIG. 1, a semiconductor light emitting device according to an embodiment of the invention includes a base portion 1 having a concaved portion 3 that defines an inner space thereof and has an opening portion, a light emitting diode chip 2 provided in the inner space of the concaved portion 3, a resin filled portion 4 including resin filled in a region defined from an inner bottom wall of the concaved portion 3 to the opening portion, and a phosphor contained resin layer 6 containing a wavelength converting substance and provided to close the opening portion of the concaved portion 3. The base portion 1 includes a material having a high thermal conducting characteristic, for instance, copper (Cu), aluminum (Al), a copper alloy, an aluminum alloy, etc. The light emitting diode chip includes a semiconductor light emitting element such as nitride semiconductor element. For example, a blue light emitting diode containing gallium nitride may be adopted as the semiconductor light emitting element.

The resin filled portion 4 includes fluorocarbon polymers and a silicone resin such as a dimethyl silicone resin. Both the dimethyl silicone resin and the fluorocarbon polymers have high transmittance and high refractive indexes, so that light emitted from the light emitting diode chip 2 can be derived outside the semiconductor light emitting device in a higher efficiency.

The phosphor contained resin layer 6 includes phosphor and a mixed resin. An example of the mixed resin includes silicone and epoxy resins or silicone and acrylic resins. When characteristics of the phosphor contained resin layer 6 is compared with those of the resin filled portion 4, a thermal expansion coefficient of the phosphor contained resin layer 6 is lower than that of the resin filled portion 4, and also, crosslink density of the phosphor contained resin layer 6 is higher than that of the resin filled portion 4. As a result, even when the resin filled portion 4 expands and deforms under high temperature atmosphere, the phosphor contained resin layer 6 that closes the opening portion of the concaved portion 3 can hardly expand and can hardly deform. As a consequence, it is possible to suppress the expansion and deformation of the resin filled portion 4, so that a wavelength of emitted light does not depart from a desirable wavelength.

The phosphor filled in the phosphor contained resin layer 6 may include a plurality of phosphors capable of emitting green, blue, red, and yellow light. In the embodiment of the present invention, the phosphor allows emission of white light in combination with a nitride semiconductor light emitting element. Generally speaking, a nitride semiconductor light emitting element has natures that a larger heat generation amount as compared with other light emitting elements and may give a great adverse influence to the deformation of the resin filled portion 4. However, in this embodiment, the high quality as to the resin filled portion 4 can be sufficiently secured, and the wavelength of the emitted light is made stable. As a result, the semiconductor light emitting device of this embodiment can emit the white light with the smaller color fluctuation than the related-art semiconductor light emitting device.

A reflecting plate portion 5 is provided on inner walls of the concaved portion 3 of the base portion 1. For example, the reflecting plate portion 5 is formed by plating the inner walls with silver or silver containing material. However, the semiconductor light emitting device may be used in the outdoor field. Exhaust gas of automobiles contains sulfur in a substantially unavoidable manner. In a case where a general-purpose semiconductor light emitting device is utilized in atmosphere containing a large amount of sulfur, silver may be reacted with sulfur to be silver sulfide (Ag₂S) Silver sulfide has a dull black color, so that it is practically difficult to obtain original reflections owned by silver.

However, according to the embodiment, since crosslink density of the phosphor contained resin layer 6 is higher than that of the resin filled portion 4, it is possible to suppress that sulfur enters into the resin filled portion 4. As a consequence, the reflecting plate portion 5 can maintain a superior reflection characteristic.

The thermal expansion coefficient of the resin filled portion 4 is, for example, 250 to 270 ppm/° C., and the density thereof is, for instance, 2 to 3.5 g/cm³. Also, the thermal expansion coefficient of the phosphor contained resin layer 6 is, for example, 70 to 75 ppm/° C., and density thereof is, for instance, 4 to 7 g/cm³. The semiconductor light emitting device of the embodiment can be effectively realized by selecting resins to meet the ranges.

According to the embodiments of the invention, the deformation caused by the expansion of the resin filled portion 4 is avoided by mixing a substance having a low expansion coefficient into a phosphor contained resin layer 6 provided in an inner space of a concaved portion 3. Since the substance having lower expansion coefficient than a resin filled portion 4 is mixed into the phosphor contained resin layer 6, even when the resin filled portion 4 expands and deforms under higher temperature atmosphere, the phosphor contained resin layer 6 that closes the opening portion can hardly expand as well as can hardly deform. As a result, it is possible to suppress the expansion and deformation of the resin filled portion 4. In addition, since molecular coupling of the above-described phosphor contained layer 6 is made closer than that of the resin filled portion 4, it is possible to avoid entering impurities contained in an atmosphere invade into the resin filled portion.

According to the embodiment of present invention, since a thermal expansion coefficient of the phosphor contained resin layer 6 is lower than that of the resin filled portion 4, it is possible to suppress that the resin filled portion 4 is deformed. As a result, it is possible to suppress that wavelengths of light which passes through the phosphor contained resin layer 6 are changed, so that color fluctuations can be suppressed. Moreover, it is possible to suppress that the impurities enter into a semiconductor chip and a reflecting plate. As a result, such a semiconductor light emitting device having high reliability can be provided.

It should be understood that the above embodiment has been merely exemplified in order to explain the inventive idea of the present invention, and therefore, does not limit the scope of the invention.

What is claimed is;

1. A semiconductor light emitting device comprising:
a base portion having a concaved portion;
a light emitting element provided in the concaved portion;
a resin filled in the concaved portion; and
a phosphor contained resin layer containing a wave converting substance and provided to close an opening portion of the concaved portion,
wherein the phosphor contained resin layer has a lower thermal expansion coefficient than the resin filled in the concaved portion.

2. The semiconductor light emitting device according to claim 1, wherein the phosphor containing resin layer has higher crosslink density than the resin filled in the concaved portion.

3. The semiconductor light emitting device according to claim 1, wherein the light emitting element comprises a nitride semiconductor light emitting device.

4. The semiconductor light emitting device according to claim 1, further comprising a reflection portion provided in the concaved portion configured to reflect light emitted from the light emitting element.

5. The semiconductor light emitting device according to claim 4, wherein the reflection portion contains sliver.

6. A semiconductor light emitting device comprising:
a base portion having a concaved portion;
a light emitting element provided in the concaved portion;
a resin filled in the concaved portion; and
a phosphor contained resin layer containing a wave converting substance and provided to close an opening portion of the concaved portion,
wherein the phosphor containing resin layer has higher crosslink density than the resin filled in the concaved portion.

7. The semiconductor light emitting device according to claim 6, wherein the light emitting element comprises a nitride semiconductor light emitting device.

8. The semiconductor light emitting device according to claim 6, further comprising a reflection portion provided in the concaved portion configured to reflect light emitted from the light emitting element.

9. The semiconductor light emitting device according to claim 8, wherein the reflection portion contains sliver.
